(19) United States
(12) Patent Application Publication
(10) Pub. No.: US 2012/0206145 A1
(43) Pub. Date: Aug. 16, 2012

(54) Array test method for organic light emitting display device and method for manufacturing the organic light emitting display device

(76) Inventors: Kwang-Hae Kim, Yongin-City (KR); Kwan-Wook Jung, Yongin-City (KR); Hun-Tae Kim, Yongin-City (KR)

(21) Appl. No.: 13/200,332

(22) Filed: Sep. 23, 2011

(30) Foreign Application Priority Data
Feb. 14, 2011 (KR) 10-2011-0012856

(51) Int. Cl. G01R 31/00; H01L 21/66

(52) U.S. Cl. 324/414; 438/16; 257/E21.521

(57) ABSTRACT

A test method of a pixel circuit array in an organic light emitting diode (OLED) display, the pixel circuit including a first capacitor connected to a first transistor, the first transistor transmitting a data signal and controlling a light emitting amount of an organic light emitting element according to a scan signal, the method including irradiating an electron beam to a first electrode terminal of the first capacitor before completing formation of the organic light emitting element, the first electrode terminal being exposed during the irradiation, and testing operation of the first transistor based on emitted secondary electrons.

### CROSS-REFERENCE TO RELATED APPLICATION

This application claims priority to and the benefit of Korean Patent Application No. 10-2011-0012856 filed in the Korean Intellectual Property Office on Feb. 14, 2011, the entire contents of which are incorporated herein by reference.

### BACKGROUND

1. Field

Example embodiments relate to a test method of a display device and to a manufacturing method thereof. More particularly, the example embodiments relate to a pixel circuit array test method of an organic light emitting diode (OLED) display and a manufacturing method of the OLED display.

2. Description of the Related Art

An organic light emitting diode (OLED) display has a self-light emitting characteristic so a separate light source is not required, and it has high quality characteristics, e.g., low power consumption, high luminance, and high reaction speed, such that it is spotlighted as a next generation display device. Also, the OLED display is applicable to a high-speed operational circuit, since it has excellent carrier mobility.

In the OLED display, transmission of a driving current of the OLED is controlled by a transistor included in each pixel circuit. Therefore, if the transistor of the pixel circuit is abnormally operated, or a wire is disconnected or short-circuited, a predetermined driving current may not be applied to the OLED.

The above information disclosed in this Background section is only for enhancement of understanding of the background of the invention and therefore it may contain information that does not form the prior art that is already known in this country to a person of ordinary skill in the art.

### SUMMARY

Exemplary embodiments provide a pixel circuit array test method of an OLED display.

Also, exemplary embodiments provide a manufacturing method of an OLED display.

According to one aspect of example embodiments, a test method of a pixel circuit array in an organic light emitting diode (OLED) display, the pixel circuit including a first capacitor connected to a first transistor, the first transistor transmitting a data signal and controlling a light emitting amount of an organic light emitting element according to a scan signal, the method including irradiating an electron beam to a first electrode terminal of the first capacitor before completing formation of the organic light emitting element, the first electrode terminal being exposed during the irradiation, and testing operation of the first transistor based on emitted secondary electrons.

The first transistor may include a gate connected to the scan signal, an input terminal connected to the data signal, and an output terminal connected to the first electrode terminal of the first capacitor, and the first capacitor may include a second electrode terminal connected to a driving voltage for supplying a current to the organic light emitting element.

The pixel circuit may further include a second transistor supplying a driving current for the organic light emitting element by corresponding to the data signal transmitted through the first transistor.

The pixel circuit may further include a third transistor and a second capacitor to compensate for a threshold voltage of the second transistor in response to a global control signal for threshold voltage compensation.

The first electrode terminal of the first capacitor may be simultaneously formed with the gate electrode of the first transistor and with an anode on a gate insulating layer, and the anode and the first electrode terminal of the first capacitor are exposed by an interlayer insulating layer covering the gate electrode.

The gate of the first transistor may be formed with a multi-layered structure including a transparent conductive layer and a metal layer, and the first electrode terminal of the first capacitor and the anode exposed by the interlayer insulating layer are formed with the transparent conductive layer.

The test method may further include a conductive layer pattern to connect a drain region of the first transistor and the second electrode terminal of the first capacitor, and a driving voltage line on the interlayer insulating layer.

According to another aspect of example embodiments, a method for manufacturing a pixel circuit array in an organic light emitting diode (OLED) display, the pixel circuit including a first transistor transmitting a data signal and controlling a light emitting amount of an organic light emitting element according to a scan signal and a first capacitor connected to the first transistor, the method including exposing a first electrode terminal among first and second electrode terminals of the first capacitor, irradiating an electron beam to the exposed first electrode terminal of the first transistor, testing an operation of the first transistor based on emitted secondary electrons, such that a pixel circuit array is determined as normal or defective, repairing a pixel circuit array that is determined to be defective, and completing formation of an organic light emitting element in the pixel circuit array that is repaired or is determined to be normal.

The first transistor may include a gate connected to the scan signal, an input terminal connected to the data signal, and an output terminal connected to the exposed first electrode terminal of the first capacitor, and the second electrode terminal of the first capacitor may be connected to a driving voltage for supplying a current to the organic light emitting element.

The pixel circuit may further include a second transistor supplying a driving current of the organic light emitting element by corresponding to the data signal transmitted through the first transistor.

The pixel circuit may further include a third transistor and a second capacitor to compensate for a threshold voltage of the second transistor in response to a global control signal for threshold voltage compensation.

The exposed first electrode terminal of the first capacitor may be simultaneously formed along with the gate of the first transistor and an anode on a gate insulating layer, and the anode and exposed first electrode terminal of the capacitor are exposed by an interlayer insulating layer covering the gate.

The gate electrode of the first transistor may be formed with a multi-layered structure including a transparent conductive layer and a metal layer, and the exposed first electrode terminal of the first capacitor exposed by the interlayer insulating layer and the anode may be formed with the transparent conductive layer.

The manufacturing method may further include forming a conductive layer pattern to connect a drain region of the first transistor and the first electrode terminal of the first capacitor, and forming a driving voltage line on the interlayer insulating layer.

The second electrode terminal of the first capacitor and an activating pattern of the first transistor may be formed under the gate insulating layer.

Repairing the pixel circuit array may be executed by an in-situ method with a test of the pixel circuit array.

### BRIEF DESCRIPTION OF THE DRAWINGS

FIG. 1 is a flowchart of a manufacturing method of an OLED display according to an exemplary embodiment.

FIG. 2 is an equivalent circuit of a unit pixel in an OLED display that is tested with an array test method according to an exemplary embodiment.

FIG. 3 is a layout view of the unit pixel shown in FIG. 2.

FIG. 4 is a cross-sectional view of the unit pixel shown in FIG. 2.

FIG. 5 is a schematic diagram of an array test method according to an exemplary embodiment.

FIG. 6 is a schematic diagram of an electron beam device applied to an array test method according to an exemplary embodiment.

### DETAILED DESCRIPTION

Advantages, features, and aspects of example embodiments will become apparent from the following description with reference to the accompanying drawings, which are set forth hereinafter. However, example embodiments are not limited to the described herein and may have various embodiments. The exemplary embodiments are provided to clearly show the present invention to those skilled in the art, and to cover various modifications and equivalent arrangements included within the spirit and scope of the appended claims. Accordingly, in various exemplary embodiments, well-known processes, well-known elements, and well-known techniques are not explained in detail to avoid ambiguous interpretation of the present invention.

Throughout this specification and the claims that follow, when it is described that an element is “coupled” to another element, the element may be “directly coupled” to the other element or “indirectly coupled” to the other element through a third element. In addition, unless explicitly described to the contrary, the word “comprise” and variations such as “comprises” or “comprising” will be understood to imply the inclusion of stated elements but not the exclusion of any other elements. The terms of a singular form may include plural forms unless referred to the contrary.

Although not specifically defined, all of the terms including the technical and scientific terms used herein have meanings understood by ordinary persons skilled in the art. The terms have specific meanings coinciding with related technical references and the present specification as well as lexical meanings. That is, the terms are not construed as ideal or formal meanings.

Exemplary embodiments described in this specification will be explained with a layout view, a cross-sectional view, and/or a schematic diagram, which is an ideal schematic diagram of the present invention. Accordingly, the exemplary views may be changed by manufacturing techniques and/or permissible errors. Further, the exemplary embodiments are not limited by the specific shapes drawn, and may include changes of the shapes that are generated according to a manufacturing process. The exemplary regions in the drawings include schematic properties, and the shapes of the exemplary regions in the drawings are to indicate the specific shapes of the regions of the elements, and not to limit the scope of the invention. Like reference numerals designate like elements throughout the specification.

A pixel circuit array test method (hereinafter, an array test method) of an OLED display according to an exemplary embodiment may be executed before a panel (cell) process for completion of the OLED among manufacturing processes of the OLED display. For example, the array test method may be executed by a method in which an electron beam (E-beam) is irradiated to an exposed electrode of a capacitor, and then an amount of emitted secondary electrons is measured to confirm normal operation of a transistor connected to the capacitor.

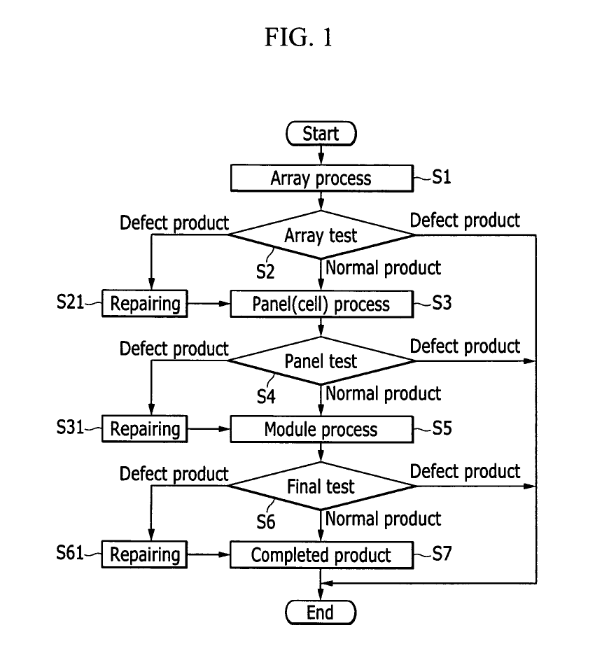

FIG. 1 is a flowchart of a manufacturing method of an OLED display according to an exemplary embodiment.

Firstly, an array process S1 of forming a pixel circuit array is performed on a substrate. The pixel circuit array may include at least two transistors and at least one capacitor. In the array process S1, an electrode of the capacitor is formed to be exposed at the highest surface. Next, an array test S2 is performed. In the array test S2, a normal operation of the transistor is tested. The pixel array that is determined to be a defective product in the array test S2 undergoes a repair process S21. If repair is impossible, subsequent processes are not executed and the manufacturing process is terminated. A pixel array that is determined to be a normal product or that is completely repaired continues to a panel (cell) process S3, where an organic emission layer and a cathode are formed to form the OLED.

Next, a panel test S4 is performed. As described previously with reference to the pixel circuit array, a panel that is determined to be a defective product in the panel test S4 undergoes a repair process S31, and when repair of the panel is impossible, subsequent processes are not executed and the process is terminated. For a panel that is determined to be a normal product or that is completely repaired, a module process S5 is performed, followed by a final test S6 to analyze final completion product and any defects. In the final test S6, a module that is determined to be a defective product undergoes a repair process S61, and when repair is impossible, the module is end-treated. As shown in FIG. 1, an operation defect of a transistor is tested after the array process S1 such that the defect of the pixel circuit array may be repaired in early stages of the manufacturing process, thereby increasing manufacturing yield. Also, for a pixel circuit array defect for which repair is possible, the panel (cell) process and the module process are not executed, thereby saving manufacturing time and manufacturing cost.

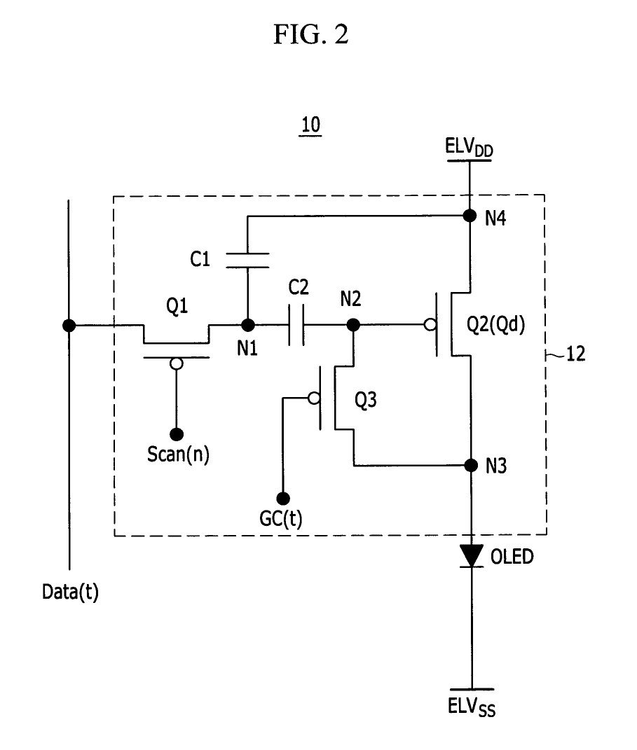

Next, a detailed method of the array test S2 will be described with reference to FIG. 2. FIG. 2 is an equivalent circuit of a unit pixel of an OLED display configured to be applied to an array test method according to an exemplary embodiment.

Each unit pixel 10 includes an organic light emitting diode OLED and a pixel circuit 12 having three transistors two capacitors (3T2C). In detail, referring to FIG. 2, the pixel circuit 12 may include first through third transistors Q1 through Q3, first capacitor C1, and second capacitor C2.

The first transistor Q1 includes a gate connected to a current scan signal scan[n], an input terminal connected to a data signal Data[t], and an output terminal connected to a first node N1. The driving transistor Qd, i.e., the second transistor Q2, includes a gate connected to the second capacitor C2 at a second node N2, an input terminal connected to a first power source at a fourth node N4, e.g., to a driving voltage ELVdd, and an output terminal connected to an anode of the organic light emitting diode OLED and an input terminal of the third transistor Q3 at a third node N3. The third transistor Q3 includes a gate connected to a global control signal GC(t) for threshold voltage compensation of the driving transistor Qd, an input terminal connected to the output terminal of the driving transistor Qd at the third node N3, and an output terminal connected to the gate of the driving transistor Qd and the second capacitor C2 at the second node N2.

The first capacitor C1 includes one terminal, i.e., a first capacitor C1 electrode, connected to one terminal of the second capacitor C2 and to the output terminal of the first transistor Q1 at the first node N1, and another terminal, i.e., a second electrode, connected to the first power source, i.e., a power source supplying a current to the organic light emitting diode OLED, at the fourth node N4. The second capacitor C2 includes one terminal, i.e., a first electrode, connected to the output terminal of the first transistor Q1 and to one terminal of the first capacitor C1 at the first node N1, and another terminal, i.e., a second electrode, connected to the gate of the driving transistor Qd and to the output terminal of the third transistor Q3 at the second node N2.

The organic light emitting diode OLED includes the anode (pixel electrode) connected to the output terminal of the driving transistor Qd and to the input terminal of the third transistor Q3 at the third node N3, and a cathode (common electrode) connected to a second power source, e.g., a common voltage ELVss.

The first transistor Q1 is a switching transistor transmitting the data signal Data[t] applied to the corresponding data line in response to the current scan signal scan[n], and controlling a light emitting amount of the organic light emitting diode OLED. The driving transistor Qd supplies the driving current of the organic light emitting diode OLED by corresponding to the data signal Data[t] transmitted to the gate through the first transistor Q1. The third transistor Q3 is a threshold voltage compensation transistor to compensate the threshold voltage of the driving transistor Qd in response to the global control signal GC[t].

The first capacitor C1 is a capacitor to store the data signal applied to the gate of the driving transistor Qd. The second capacitor C2 is a capacitor to control the threshold voltage of the driving transistor Qd.

The first to third transistors Q1, Q2, and Q3 may be p-channel field effect transistors. As an example of the field effect transistor, a thin film transistor (TFT) may be used. The channel type of the first to the third transistors Q1, Q2, and Q3 may be changed to a n-channel type, and the waveform of the signal driving them may be reversed.

In the array test according to an exemplary embodiment, the voltage of the first capacitor C1 electrode at the first node N1 is measured. If the first transistor Q1 is not normally operated and a leakage current is generated, the voltage of the first capacitor C1 electrode does not have the original input value but has a different value at the first node N1. Accordingly, the normal operation of the first transistor Q1 may be easily tested by measuring the voltage of the first capacitor C1 electrode.

FIG. 2 shows the pixel circuit 12 (3T2C). However, example embodiments are not limited thereto, and the array test method according to example embodiments may be also applied to other pixel circuit configurations, e.g., a 2T1C pixel circuit without the third transistor Q3 and without the second capacitor C2 or a pixel circuit including various combinations of other transistors and other capacitors instead of the third transistor Q3 and the second capacitor C2.

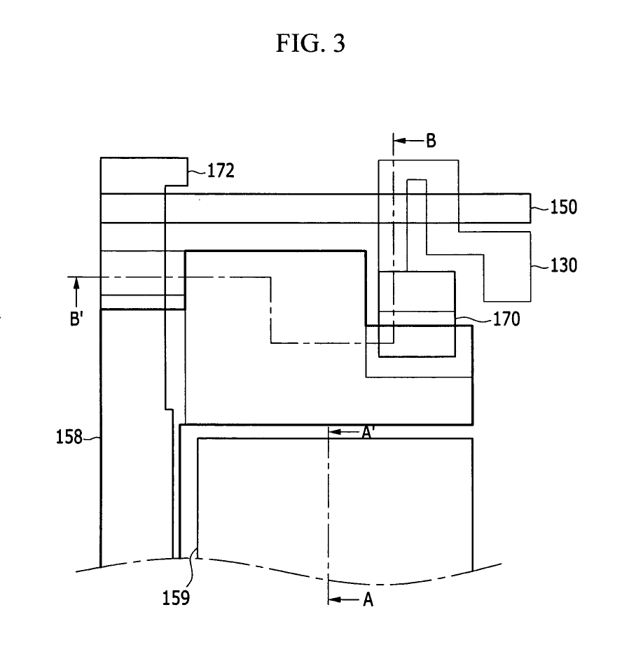

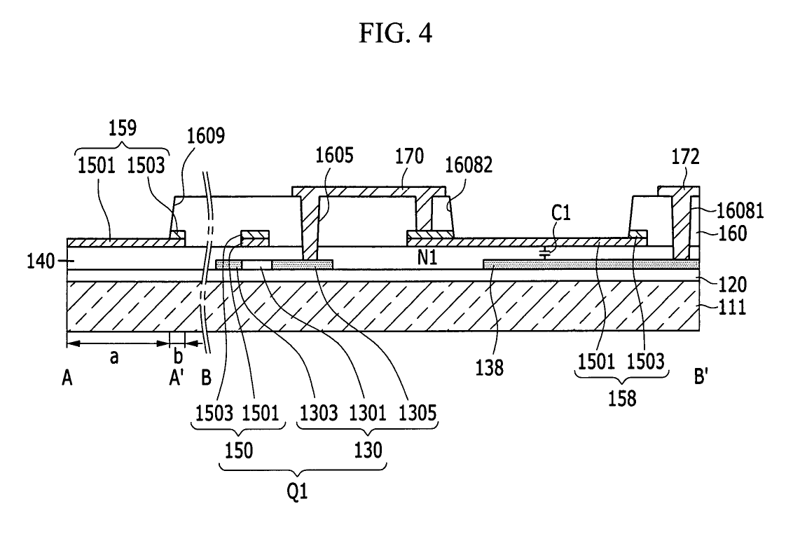

The array process S1 shown in the flowchart of FIG. 1 will now be described with reference to FIG. 3 and FIG. 4, which show a layout view and a cross-sectional view, respectively, of a pixel in the unit pixel 10 shown in FIG. 2. The layout to realize the pixel 10 may be variously changed by a person of ordinary skill in the art, so FIG. 3 focuses only on the first transistor Q1 and the first capacitor C1 that are applied to the array test in order to avoid ambiguous interpretation.

Firstly, a substrate 111 is provided. For example, the substrate 111 may be a transparent insulating substrate made of, e.g., glass, quartz, ceramic, or plastic. In another example, the substrate 111 may be a metallic substrate made of, e.g., a stainless steel. Further, when the substrate 111 is made of plastic, it may be a flexible substrate.

A buffer layer 120 is formed on the substrate 111. The buffer layer 120 can be formed to be single-layered or multi-layered including at least one of various insulating layers known to a skilled person, e.g., a silicon oxide (SiOₓ) film, a silicon nitride (SiN_{y}) film, or a silicon oxide and nitride (SiOxN_{y}) film by using a chemical vapor deposition method or a physical vapor deposition method. The buffer layer 120 prevents permeation of undesired elements such as impurities or moisture, and smoothes the surface. Therefore, the buffer layer 120 can be omitted depending on the type of substrate 111 and process conditions.

An activating pattern 130 and the other terminal 138, i.e., the second electrode terminal, of the first capacitor C1 connected to the first power source ELVdd at the fourth node N4 are formed on the buffer layer 120. A polysilicon layer is used to form the activating pattern 130 and the other terminal 138 of the first capacitor C1. The first activating pattern 130 shown in the drawing is an activating pattern for the first transistor Q1.

A gate insulating layer 140 is formed on the activating pattern 130. The gate insulating layer 140 can be formed by including at least one of insulating materials known to a skilled person, e.g., silicon nitride (SiNₓ), silicon oxide (SiO₂), or tetra ethyl ortho silicate (TEOS).

A gate electrode 150, one terminal 158, i.e., the first electrode terminal, of the first capacitor C1 connected to the first transistor Q1 at the first node N1, and an anode 159 are formed on the gate insulating layer 140.

The gate electrode 150 is formed to overlap a channel region 1301 of the activating pattern 130. An impurity is doped by using the gate electrode 150 as a mask such that the channel region 1301, a source region 1303, and a drain region 1305 doped with a p+ type impurity are defined in the activating pattern 130. Here, the doped ion material may be the P-type impurity, e.g., boron, gallium, and/or indium. In the first to third transistors Q1, Q2, and Q3, a TFT of a PMOS structure using the P-type impurity may be applied. However, example embodiments are not limited thereto, and a TFT of a NMOS structure or a CMOS structure may be used.

The one terminal 158 of the first capacitor C1 overlaps the other terminal 138, thereby completing the first capacitor C1.

The anode 159 is divided into a light emitting region “a” and a non-light-emitting region “b”. The light emitting region “a” of the anode 159 may transmit light.

An interlayer insulating layer 160 is formed on the gate electrode 150, the one terminal 158 of the first capacitor C1, and the anode 159. The interlayer insulating layer 160 can be formed by including at least one of insulating materials known to a skilled person, e.g., silicon nitride (SiNₓ), silicon oxide (SiO₂), or TEOS, like the gate insulating layer 140.

The interlayer insulating layer 160 includes a contact hole 1605 exposing the drain region 1305 of the semiconductor layer 135, a contact hole 16081 exposing the other terminal 138 of the first capacitor C1, a contact hole 16082 exposing the other terminal 158 of the first capacitor C1, and a contact hole 1609 exposing the light emitting region “a” of the anode 159.

A conductive layer pattern 170 to connect the drain region 1305 of the first transistor Q1 and the one terminal 158 of the first capacitor C1, and a first power source ELVdd line 172 contacting the other terminal 138 of the first capacitor C1 are formed on the interlayer insulating layer 160.

Referring to FIG. 4, while the gate electrode 150 is formed with a multi-layer structure including a transparent conductive layer 1501 and a metal layer 1503, a portion of the one terminal 158 of the first capacitor C1 exposed through the contact hole 16082 and the light emitting region a of the anode 159 exposed through the contact hole 1609 are formed with a single layer of the transparent conductive layer 1501. This is because the patterning of the conductive layer pattern 170 and the first power source ELVdd line 172 and the definition of the light emitting region “a” of the anode 159 are executed by one etching step.

In detail, the conductive layer 1501 and the metal layer 1503 are sequentially deposited and patterned on the gate insulating layer 140 to form the gate electrode 150, a pattern for the one terminal of the first capacitor C1, and a pattern for the anode. The transparent conductive layer 1501 may be made of a transparent conducting material, e.g., indium tin oxide (ITO), indium zinc oxide (IZO), zinc oxide ZnO), or indium oxide (In₂O₃). The metal layer 1503 may be formed of a metal having a low resistance characteristic. For example, the metal layer 1503 may be formed of a multilayer including a metal layer formed of, e.g., at least one of copper (Cu) and aluminum (Al), and a metal layer formed of, e.g., molybdenum (Mo).

Next, the interlayer insulating layer 160 is formed, and after forming the contact holes 1605, 16081, 16082, and 1609, an additional metal layer is deposited, i.e., a metal layer to form the conductive layer pattern 170 and the first power source ELVdd line 172. When the additional metal layer is formed of the same material as the metal layer 1503, the manufacturing process may be simplified. Next, the additional metal layer is etched by one etching process to complete the conductive layer pattern 170 and the first power source ELVdd line 172. Here, the metal layer 1503 is simultaneously removed. As a result, the light emitting region “a” of the anode 159 and the one terminal 158 of the first capacitor C1 exposed through the contact hole 16082 are only formed of the transparent conductive layer 1501. Accordingly, the non-light-emitting region “b” of the anode 159 is made of two layers including the transparent conductive layer 1501 and the metal layer 1503, and the light emitting region “a” is only made of the transparent conductive layer 1501. Also, in the one terminal 158 of the first capacitor C1, the portion exposed through the contact hole 16082 is only made of the transparent conductive layer 1501 and the portion that is not exposed is made of two layers including the transparent conductive layer 1501 and the metal layer 1503.

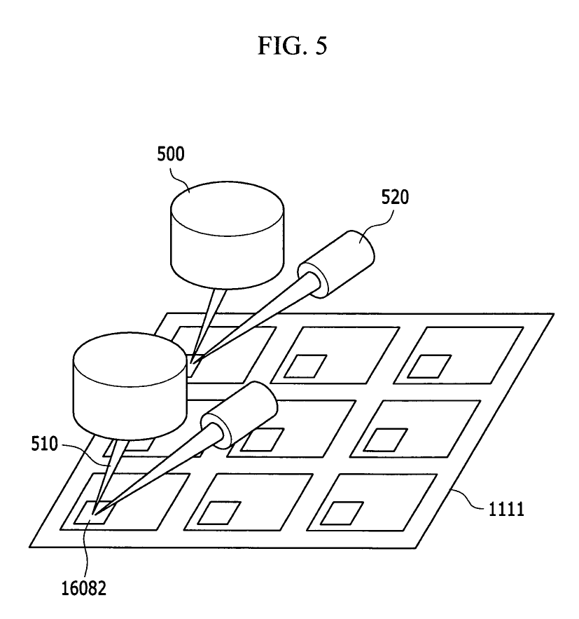

As described above, when the array process S1 to form the pixel circuit 12 (FIG. 2) is completed, the array test S2 is performed, as will be described with reference to FIG. 5. FIG. 5 is a schematic diagram of an array test method according to an exemplary embodiment.

Referring to FIG. 5, after a substrate 1111 that is finished in the array process S1 is loaded to an electron beam device, the first transistor Q1 is turned on to charge the first capacitor C1. The charged capacitance corresponds to the difference between the voltage applied to the data line (Data[t] of FIG. 2) and the voltage of the first power source voltage ELVdd. Next, an electron beam EB 510 emitted from an electron emitting source 500 of the electron beam device is irradiated to the one terminal 158 of the first capacitor C1 exposed through the contact hole 16082. By this irradiation, secondary electrons SE are emitted from one terminal electrode 158 of the first capacitor C1, and the secondary electrons are detected by an electron detecting means 520. The secondary electrons are related to the voltage of the irradiated position. Accordingly, the normal operation of the first transistor Q1 as the switching transistor may be confirmed based on the measured value. If the first transistor Q1 is not normally operated or the leakage current is generated, the measured value is different from the calculated value of the voltage applied to the first node N1.

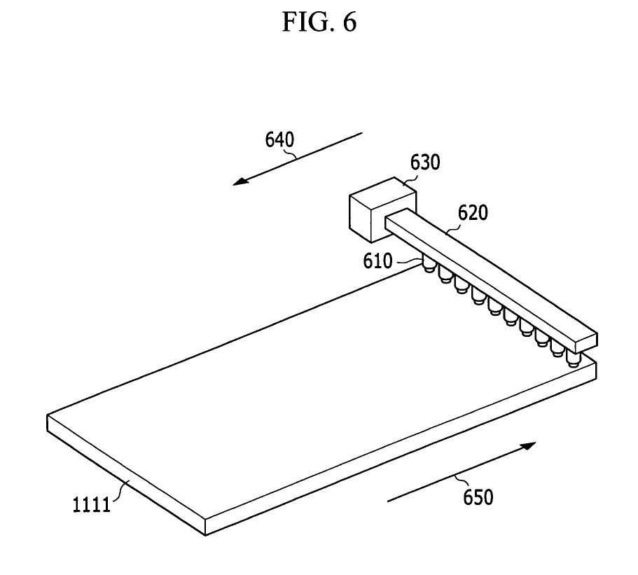

The array test S2 is possible with a high speed within a short time in an OLED display of a large size by using the electron beam device 600 shown in FIG. 6.

Referring to FIG. 6, the electron beam device 600 includes a plurality of micro-columns 610 respectively having the electron emitting source (500 of FIG. 5) and the electron detecting means (520 of FIG. 5), arranged in one line, and fixed to a fixing axis 620. The fixing axis 620 is moved in a first direction 650 by a driver 630, and the electron beam is entirely irradiated to one line such that a plurality of pixel circuits that are disposed in one line may be simultaneously measured. A plurality of micro-columns 610 that are arranged in one line are fixed to the fixing axis 620 such that the test speed may be further improved. Also, instead of moving the fixing axis 620, the substrate 1111 that is completed in the array process S1 is moved in a second direction 650, thereby performing the test.

Referring to FIG. 5 and FIG. 6, when the above-described array test S2 is completed, a normal product is loaded to a subsequent panel (cell) process S3, and a defective product is loaded to the repairing process S21 and, subsequently, to the panel (cell) process S3. Under the repair process S21, the electron beam device 600 shown in FIG. 6 may be applied in an in-situ method as it is.

According to an exemplary embodiment, operability of a transistor is tested in an early stage of the manufacturing process through an array test, i.e., before the panel (cell) process, so that potential defects of a pixel circuit array may be detected and repaired at an early manufacturing stage. As such, the manufacturing yield may be increased. Also, the panel (cell) process and the module process are not performed for pixel circuit arrays with irreparable defects, so manufacturing time and costs may be minimized. Therefore, according to example embodiments, an array test method of an OLED display may easily and correctly test performance of a transistor for a pixel circuit array before formation on OLED therein, i.e., so defects may be repaired or panel/module processes manufacturing may be stopped before forming the OLED, thereby improving yield while reducing costs.

The drawings and the detailed description described above are examples for the present invention and are provided to explain the present invention, and the scope of the present invention described in the claims is not limited thereto. Therefore, it will be appreciated to those skilled in the art that various modifications may be made and other equivalent embodiments are available. Accordingly, the actual scope of the present invention must be determined by the spirit of the appended claims.

<Description of Symbols>

| | |
|---|---|
| 10, 20: pixel | 12, 22: pixel circuit |
| Q1, Q2, Q3: transistor | N1, N2, N3, N4: node |
| C1, C2: capacitor | OLED: organic light emitting diode |
| 111: substrate | 120: buffer layer |
| 130: activating pattern | 138: other terminal of a capacitor |
| 140: gate insulating layer | 150: gate electrode |
| 158: one terminal of a capacitor | 159: anode |
| 160: interlayer insulating layer | 1605, 16081, 16082, 1609: contact hole |
| 500: electron emitting source | 510: electron beam |
| 520: electron detecting means | 600: electron beam device |

What is claimed is:

1. A test method of a pixel circuit array in an organic light emitting diode (OLED) display, the pixel circuit including a first capacitor connected to a first transistor, the first transistor transmitting a data signal and controlling a light emitting amount of an organic light emitting element according to a scan signal, the method comprising:
irradiating an electron beam to a first electrode terminal of the first capacitor before completing formation of the organic light emitting element; and
testing operation of the first transistor based on emitted secondary electrons.

2. The test method of claim 1, wherein:
the first transistor includes a gate connected to the scan signal, an input terminal connected to the data signal, and an output terminal connected to the first electrode terminal of the first capacitor, and
the first capacitor includes a second electrode terminal connected to a driving voltage for supplying a current to the organic light emitting element.

3. The test method of claim 2, wherein the pixel circuit further comprises a second transistor supplying a driving current for the organic light emitting element by corresponding to the data signal transmitted through the first transistor.

4. The test method of claim 3, wherein the pixel circuit further comprises a third transistor and a second capacitor to compensate for a threshold voltage of the second transistor in response to a global control signal for threshold voltage compensation.

5. The test method of claim 2, wherein:
the first electrode terminal of the first capacitor is simultaneously formed with the gate electrode of the first transistor and with an anode on a gate insulating layer, and
the anode and the first electrode terminal of the first capacitor are exposed by an interlayer insulating layer covering the gate electrode.

6. The test method of claim 5, wherein the gate of the first transistor is formed with a multi-layered structure including a transparent conductive layer and a metal layer, and the first electrode terminal of the first capacitor and the anode exposed by the interlayer insulating layer are formed with the transparent conductive layer.

7. The test method of claim 5, further comprising:
a conductive layer pattern to connect a drain region of the first transistor and the second electrode terminal of the first capacitor; and
a driving voltage line on the interlayer insulating layer.

8. A method for manufacturing a pixel circuit array in an organic light emitting diode (OLED) display, the pixel circuit including a first transistor transmitting a data signal and controlling a light emitting amount of an organic light emitting element according to a scan signal and a first capacitor connected to the first transistor, the method comprising:
exposing a first electrode terminal among first and second electrode terminals of the first capacitor;
irradiating an electron beam to the exposed first electrode terminal of the first transistor:
testing an operation of the first transistor based on emitted secondary electrons, such that a pixel circuit array is determined as normal or defective;
repairing a pixel circuit array that is determined to be defective; and
completing formation of an organic light emitting element in the pixel circuit array that is repaired or is determined to be normal.

9. The method of claim 8, wherein the first transistor includes a gate connected to the scan signal, an input terminal connected to the data signal, and an output terminal connected to the exposed first electrode terminal of the first capacitor, and the second electrode terminal of the first capacitor is connected to a driving voltage for supplying a current to the organic light emitting element.

10. The method of claim 9, wherein the pixel circuit further comprises a second transistor supplying a driving current of the organic light emitting element by corresponding to the data signal transmitted through the first transistor.

11. The method of claim 10, wherein the pixel circuit further comprises a third transistor and a second capacitor to compensate for a threshold voltage of the second transistor in response to a global control signal for threshold voltage compensation.

12. The manufacturing method of claim 9, wherein:
the exposed first electrode terminal of the first capacitor is simultaneously formed along with the gate of the first transistor and an anode on a gate insulating layer, and
the anode and exposed first electrode terminal of the capacitor are exposed by an interlayer insulating layer covering the gate.

13. The manufacturing method of claim 12, wherein the gate electrode of the first transistor is formed with a multi-layered structure including a transparent conductive layer and a metal layer, and the exposed first electrode terminal of the first capacitor exposed by the interlayer insulating layer and the anode are formed with the transparent conductive layer.

14. The manufacturing method of claim 12, further comprising forming a conductive layer pattern to connect a drain region of the first transistor and the first electrode terminal of the first capacitor, and forming a driving voltage line on the interlayer insulating layer.

15. The manufacturing method of claim 12, wherein the second electrode terminal of the first capacitor and an activating pattern of the first transistor are formed under the gate insulating layer.

16. The manufacturing method of claim 8, wherein repairing the pixel circuit array is executed by an in-situ method with a test of the pixel circuit array.
